(19) United States
(12) Patent Application Publication
(10) Pub. No.: US 2022/0266505 A1
(43) Pub. Date: Aug. 25, 2022

(54) METHOD FOR MANUFACTURING A THREE-DIMENSIONAL OBJECT OR FOR MODIFYING THE SURFACE STATE OF A PREFORMED OBJECT BY PHOTO-POLYMERIZATION

(71) Applicants: CENTRE NATIONAL DE LA RECHERCHE SCIENTIFIQUE (CNRS), Paris (FR); UNIVERSITE D'AIX-MARSEILLE (AMU), Marseille (FR); ECOLE CENTRALE DE MARSEILLE, Marseille (FR)

(72) Inventors: Claude Amra, Marseille (FR); Jean-Claude André, Nancy (FR); Laurent Gallais-During, Pertuis (FR); Myriam Zerrad, Marseille (FR)

(73) Assignees: CENTRE NATIONAL DE LA RECHERCHE SCIENTIFIQUE (CNRS), Paris (FR); UNIVERSITE D'AIX-MARSEILLE (AMU), Marseille (FR); ECOLE CENTRALE DE MARSEILLE, Marseille (FR)

(21) Appl. No.: 17/631,570

(22) PCT Filed: Jul. 22, 2020
(86) PCT No.: PCT/EP2020/070623

§ 371 Date: Jan. 31, 2022

(30) Foreign Application Priority Data
Jul. 30, 2019 (FR) FR1908646

(51) Int. Cl. B29C 64/106

(52) U.S. Cl. CPC B29C 64/106; B33Y 10/00

(57) ABSTRACT

The method for manufacturing a three-dimensional object or for modifying the surface state of a preformed object by local polymerisation of monomers or oligomers, the polymerisation being initiated by mono-photon or multi-photon absorption in an area to be polymerised, includes: —introducing into a vessel with light-transparent walls a reaction medium comprising polymerisable monomers or oligomers, a polymerisation inhibitor, an indicator of the amount of the inhibitor and a photochemical polymerisation initiator; —initiating the polymerisation of the monomers or oligomers; —indicating the amount of inhibitor present in the reaction medium; —controlling the amount of light emitted by the irradiation system relative to the amount of inhibitor indicated by the indicator; and —switching to a following zone to be polymerised by moving the object and/or the focused light beam.

### TECHNICAL FIELD OF THE INVENTION

The present invention relates to a method for manufacturing a three-dimensional object or for modifying the surface state of a preformed object, by local polymerization of mono-functional or multi-functional monomers or mono-functional or multi-functional oligomers, said polymerization being initiated by mono-photon or multi-photon absorption.

### PRIOR ART

The invention relates to the field of three-dimensional printing (3D printing). 3D printing in its additive manufacturing component covers various methods which have in common that they allow the manufacture of objects by depositing successive extremely thin layers of material, layers which are solidified over time by a local energy source. Conventionally, these methods are based on stereo-lithography, the sintering of metal powder or the extrusion of a molten plastic wire.

In 2015, a method called CLIP (Continuous Liquid Interface Production) developed by the Company CARBON 3D™ proposes to use a defect in certain radical polymerization kinetics. This method is shown schematically in FIG. 1. In the CLIP method, the irradiation is carried out by a continuous sequence of UV images generated by a digital light projector. The oxygen diffuses through a wall transparent to light and permeable to oxygen in the air, then by molecular diffusion within the resin, which is fluid. The object under construction is, in a way, “pulled” upwards. However, this method requires the use of resins (typically acrylic resins), the reaction of which must be sensitive to oxygen and which are sufficiently fluid to allow both the transfer of oxygen into the reactive fluid and limitation of the mechanical stresses, associated with the viscosity of the resin, between the object under construction and the light entry window.

Moreover, in 2016, André, Gallais and Amra proposed to use the principles of sequential or simultaneous bi-photon absorption in order to initiate, in space, polymerization reactions (patent application in France FR16/59211 of 28 Sep. 2016 entitled “Method for the production of a three-dimensional object by a multi-photon photo-polymerization process and associated device”). This method does not require the formation of resin layers, but requires the use of pulsed light sources. The principle of the method is shown schematically in FIG. 2. By moving the focused light beams in a transparent medium, a local transformation of the medium is expected. It may be a matter of populating an electronically excited state precursor of the species involved in the initiation, either by sequential absorption requiring passage through an intermediate electron excited state, or by simultaneous absorption of several photons.

Simulations were performed to evaluate the efficiency of one-photon, space-based photo-polymerization methods wherein a polymerization inhibitor, that is to say, for example, oxygen, is consumed by light, for the creation, at a point, of a voxel. The voxel is the acronym for “volumetric pixel”. A simulation of the production of a “flat” object, in practice a quarter of a circle, was thus carried out as described in pages 36, 37 and 41 of the document “From additive manufacturing to 3D/4D printing”, volume 2, J. C. André (31 Mar. 2017). Unfortunately, the simulated method does not allow the achievement of the desired object. It appears in fact difficult to produce a complete object from a mono-photon process, because it is difficult to always be in conditions where the zones which must remain liquid do not exceed the consumption threshold of the inhibitors. In the presence of absorbed light, oxygen (like other radical inhibitors such as hydroquinone or similar products generally used as stabilizers to safeguard the quality of resins), present in the reactive solution containing a filled or unfilled resin, is consumed. The curve presented in FIG. 3 shows three zones corresponding to the consumption of oxygen, to the actual polymerization followed by an end in the form of crosslinking. The area between 0 and T1 is substantially proportional to the local oxygen concentration. In a one-photon polymerization method, the light is focused in the vicinity of the area to be polymerized. However, in the zones concerned by the passage of light, but not concerned by the polymerization zone, in particular in the zones adjacent to the polymerization zone, the weak absorption by the photochemical initiator leads to the start of consumption of the oxygen. A schematic and qualitative representation of the oxygen concentration present in the reaction medium, for different irradiation times by a focused light source, is given in FIG. 4. It appears from this figure that the longer the irradiation time, even focused, the more oxygen is consumed. Consequently, for the polymerization of new zones, when under conditions where the oxygen concentration is the result of the “history” of polymerization which the reactive medium will have undergone, which will potentially generate a propagation of the polymerization in areas where polymerization is not desired.

In a multi-photon polymerization method and, in particular a two-photon polymerization method, oxygen is mainly consumed in the focal zone (due to the non-linearity of the phenomenon). The propagation of the polymerization in zones where the polymerization is not desired is therefore more easily controlled. However, the consumption of oxygen in the entire reactor can become of concern if the number of voxels, multiplied by the volume of this element, becomes significant with respect to the volume of the reactor.

In this context, there is a need to create means for manufacturing an object in three dimensions, or even modifying the surface state of an object, by photo-polymerization, which allow to take into account the consumption of polymerization inhibitor (regardless of which inhibitor it may be) in the zone to be polymerized in order to control the polymerized zones and thus to improve the resolution of the manufactured object.

### SUMMARY OF THE INVENTION

In view of the above, a technical problem which the invention proposes to solve is to control the zones to be photo-polymerized in order to improve the resolution of a three-dimensional object to be formed or of the surface of a preformed object.

The first object of the solution of the invention to this technical problem is a method for manufacturing a three-dimensional object or for modifying the surface state of a preformed object, by local polymerization of monomers or oligomers, said polymerization being initiated by mono-photon or multi-photon absorption, in a zone to be polymerized, comprising the following steps:
introducing, into a vessel with light-transparent walls, a reaction medium comprising polymerizable monomers or oligomers, a polymerization inhibitor, an indicator of the amount of said inhibitor and a polymerization initiator;
initiating the polymerization of the monomers and/or oligomers, in the zone to be polymerized, in the reaction medium, by an irradiation system allowing the emission of a locally focused light beam, through the transparent walls of said vessel;
indicating the amount of inhibitor present in the zone to be polymerized, by the indicator of the amount of inhibitor;
controlling the amount of light emitted by the irradiation system, in the zone to be polymerized, relative to the amount of inhibitor indicated by the indicator; and
switching to a following zone to be polymerized, in the reaction medium, by means for moving the object and/or the focused light beam.

Thus, the method of the invention allows to follow the evolution of the amount of inhibitor in the reaction medium during the initiation of the polymerization and to control the irradiation to this amount in order to polymerize only one specifically determined zone, voxel by voxel. In other words, this method allows contactless measurement to follow the progress of the polymerization, in the depth of the reaction medium, and thus to control the amount of light relative to the progress of the polymerization reaction. This method also allows not to go through the formation of successive layers to manufacture the three-dimensional object, or to modify the surface of a preformed object.

Advantageously, —the inhibitor is selected from oxygen or hydroquinone; —the indicator is an optical indicator of the amount of inhibitor and said indication of the amount of inhibitor comprises measuring the light intensity emitted by the optical indicator using an optical sensor; —the irradiation system further comprises an excitation system at an absorption wavelength of the optical indicator of the amount of inhibitor; —the light intensity of the optical indicator of the amount of inhibitor is measured continuously and/or over time; —the indicator is a fluorescent or phosphorescent indicator, the local intensity of fluorescence or phosphorescence of which varies according to the amount of inhibitor; —the indicator is selected from 2,3-butanedione, 2,3-propanedione, 2,3-bornanedione, benzene or pyrene; —the monomers or oligomers are acrylic monomers or oligomers; and—the means for moving the object and/or the focused light beam allow movement along five axes of said object and/or said focused light beam, said five axes being formed of three linear axes synchronized with two rotary axes.

The second object of the invention is a reaction medium for the manufacture of a three-dimensional object or the modification of the surface state of a preformed object as defined in the invention, comprising polymerizable monomers or oligomers or mixtures thereof, a polymerization inhibitor, an indicator of the amount of said inhibitor and a polymerization initiator.

The third object of the invention is the use of an indicator of the amount of inhibitor as defined in the invention, or of a reaction medium as defined in the invention, to trigger the switching to a following zone to be polymerized in a reaction medium, during a polymerization reaction initiated by mono-photon or multi-photon absorption.

### BRIEF DESCRIPTION OF THE FIGURES

Other features, purposes and advantages of the present invention will become apparent upon reading the detailed description which follows and with regard to the figures given by way of non-limiting example and wherein:

FIG. 1 shows a method of the prior art, called CLIP method, wherein the object being formed is “pulled” upwards allowing to dispense with the formation of successive layers;

FIG. 2 schematically shows the initiation of polymerization by sequential (left) or simultaneous (right) bi-photon absorption, followed by polymerization;

FIG. 3 schematically shows the kinetic curve of a typical polymerization, showing three distinct zones: zone I corresponding to the oxygen consumption at the start of polymerization, zone II corresponding to polymerization and zone III corresponding to crosslinking at the end of polymerization;

FIG. 4 represents the influence of the irradiation time on the consumption of oxygen, which inhibits polymerization: the longer the focused irradiation time, the more oxygen is consumed locally, at the focal point;

FIG. 5 shows the emission, by phosphorescence, of 2,3-butanedione (commonly called biacetyl) used as an indicator, during the photo-polymerization reaction of a polymerizable monomer 1,6-hexanediol-diacrylate, according to the invention;

FIG. 6 shows the evolution of the inhibitor concentration and the evolution of the luminescence emission signal of the optical indicator, as a function of the irradiation time;

FIG. 7 illustrates a one-photon photochemical initiation process in the case of benzophenone;

FIG. 8 shows a device using a parabolic mirror for focusing the beam emitted by the irradiation system according to the method;

FIG. 9 schematically shows another device using a focusing of the beam emitted by the irradiation system according to the method, the object under construction being linked to a 5-axis support allowing it to be animated along these axes; this device further comprises a recycling system allowing, for example, the reaction medium to be regularly supplied with polymerization inhibitor; and

FIG. 10 illustrates the principle of the advantage of a change in resolution for a distance z, and over which Δz and Δzz represent two different resolutions related together, for example, by the relation Δz=10.Δzz.

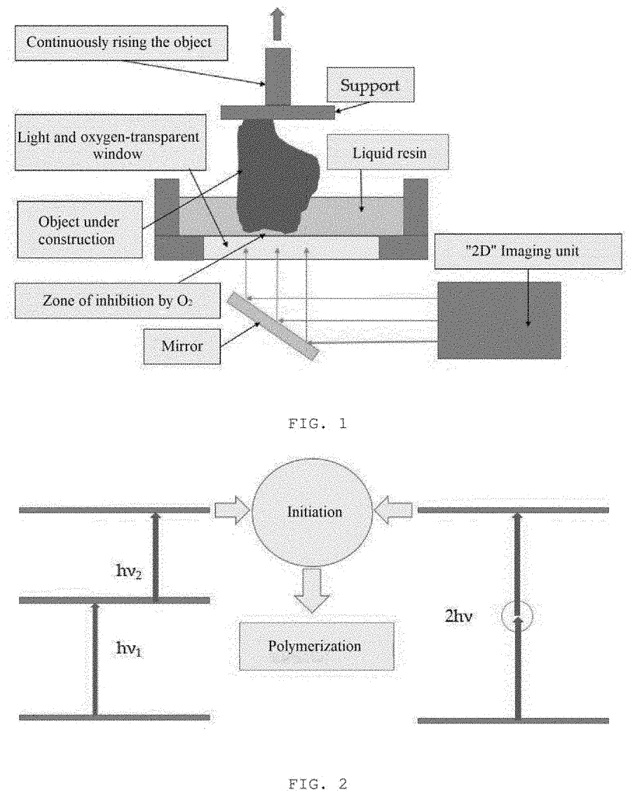

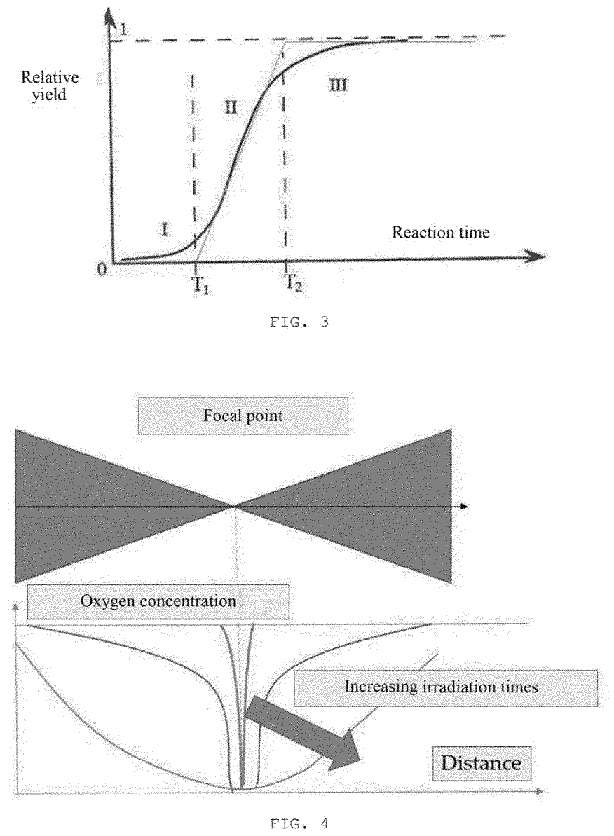

### DETAILED DESCRIPTION OF THE INVENTION

According to the present invention, the terms “from . . . to . . . ” or “between . . . and . . . ”, used to define intervals of values must be understood as incorporating the lower and upper limits of these intervals.

For the purposes of the present invention, the term “voxel” defines the predetermined zone of the reaction medium to be polymerized.

The object of the invention relates to a method for manufacturing a three-dimensional object or for modifying the surface state of a preformed object. When the object is preformed, it can be obtained by any technique known to the person skilled in the art, including by the method of the present invention.

The method of the invention implements a polymerization of monomers or oligomers, the first step of which comprises introducing a reaction medium into a vessel with light-transparent walls. According to the invention, a “vessel with light-transparent walls” is understood to mean a vessel whose walls do not absorb (or only slightly), or deflect, the light beam emitted by the irradiation system. The vessel can be made of any material known to the person skilled in the art, such as glass or quartz.

The reaction medium comprises “polymerizable monomers or oligomers”. According to the invention, the polymerizable monomers or oligomers are fluid resins known to the person skilled in the art for their sensitivity, during photochemical initiation, to the presence of inhibitors which consume the free radicals produced in the photochemical process subsequent to absorption. They are, in particular, selected from acrylic monomers or oligomers. Preferably, the polymerizable monomer of the invention is 1,6-hexanediol-diacrylate, also called HDDA below.

The reaction medium also comprises “a polymerization inhibitor”. According to one embodiment of the invention, this polymerization inhibitor is selected from oxygen or hydroquinone, preferably oxygen. Oxygen is a conventional inhibitor of radical polymerizations. It is present at a rate of the order of 3.10⁻³ in molar fraction in hydrocarbon compounds such as acrylic resins, that is to say about 1 g/liter at atmospheric pressure for pure oxygen. In the air this is about 0.2 g/liter.

If we have a concentrated flow according to a law of the type

$$F = F 0 / {d}^{2} \qquad [ math 1 ]$$

where F0 is the input flow and d the distance;

and if the irradiation time is T, then the time at the end of which the oxygen will be consumed, for a distance d, is given by the equation

$$T = ( K . {d}^{3} . [ {O}_{2} ] ) / F 0 \qquad [ math 2 ]$$

where K is a constant depending on the reaction medium.

This equation can be rewritten as follows

$$d = {( F 0. T / ( K . [ {O}_{2} ] ) )}^{1 / 3} \qquad [ math 3 ]$$

showing that, for a given resolution, in other words, for a small distance d, and for a given time, a better resolution is obtained when the medium contains more oxygen (with however an effect to the power ⅓). Thus, it may be advantageous for a given resolution to act on the oxygen concentration in the reaction medium. Conversely, if the oxygen concentration in the solution is changed, the size of the voxels is changed. Advantageously, the vicinity of the object under construction, in the reaction medium, is replenished with oxygen either by mixing the fluid composing the reaction medium, or by a system for recycling the reaction medium during which air bubbling can be performed.

The reaction medium also comprises “an indicator of the amount of said inhibitor”. The indicator of the amount of inhibitor is a molecular probe allowing to indicate the amount of inhibitor present in a considered zone. The indicator of the amount of inhibitor sends a different signal when it is in the presence or absence of the polymerization inhibitor. This indicator can in particular be an optical indicator of the amount of inhibitor, and in particular an optical indicator of the absence, apart from traces, of the inhibitor. According to one embodiment of the invention, the indicator of the amount of said inhibitor is a luminescent optical indicator, that is to say fluorescent and/or phosphorescent, at room temperature, the local luminescence intensity of which varies depending on the amount of inhibitor, and in particular, the local luminescence intensity of which reaches a maximum in the absence of inhibitor. Advantageously, the choice of the optical indicator is determined, among others, by the excitation wavelength of the polymerization initiator, and vice versa. The optical indicator is preferably selected from 2,3-butanedione, 2,3-propanedione, 2,3-bornanedione, benzene or pyrene. 2,3-Bornanedione is also hereafter referred to as camphorquinone. According to a preferred embodiment, the optical indicator of the amount of inhibitor is a phosphorescent optical indicator such as 2,3-butanedione, also called biacetyl or diacetyl below.

Biacetyl is the preferred phosphorescent optical indicator because of its high phosphorescence quantum yield, of the order of 0.15, in a medium such as a resin, at room temperature and in the absence of oxygen. Biacetyl is also preferred because of the long lifetime of the triplet emissive state of this compound, in a medium such as a resin, at room temperature and in the absence of oxygen, of the order of one millisecond. It is recalled that oxygen reacts according to a rate constant specific to a process limited by diffusion, at the molecular level: under conditions where the viscosity of the fluid is of the order of 1 Poise, 10⁻⁷ mole·l⁻¹ correspond to an amplitude of the electronic emission signal divided by two relative to a zero oxygen concentration. The method is therefore very sensitive to the presence of the inhibitor. As a remark, when the material becomes polymerized, its viscosity increases notably and in the polymerized zones, the sensitivity to oxygen becomes much lower (at the limit, the whole object for its already polymerized part is phosphorescent). According to another embodiment, the optical indicator is a fluorescent optical indicator. In this case, and to take into account the competition between transport at the molecular level of oxygen, in other words the viscosity of the reaction medium, and luminescence, it is necessary to have available singlet electronic states whose lifetime is as long as possible, for reasons of selectivity and ease of use. According to this particular embodiment, the preferred fluorescent optical indicator is pyrene, the fluorescence of which, in a medium such as a resin, at room temperature and in the absence of oxygen, has, on the one hand, a difference between the excitation wavelength and emission wavelength of the order of 50 nm which allows to selectively observe the fluorescence of this compound using conventional optical filters known to the person skilled in the art, and on the other hand, a lifetime of the singlet excited state of pyrene, of the order of 400 ns, which is sufficiently long to be observed reliably. In this case, the fluorescence of the molecular tracer for a fluid whose viscosity is 1 Poise, when the oxygen concentration reaches a few 10⁻² mole·l⁻¹, sees its amplitude divided by 2 relative to a situation where the fluid is oxygen free. According to one embodiment, the indicator of the amount of inhibitor is dissolved in the resin formed of polymerizable monomers or oligomers, at a concentration of the order of a few one per thousand (%), in other words at a concentration sufficient for the emission of light, by phosphorescence or fluorescence, to be detectable without ambiguity by any means known to the person skilled in the art.

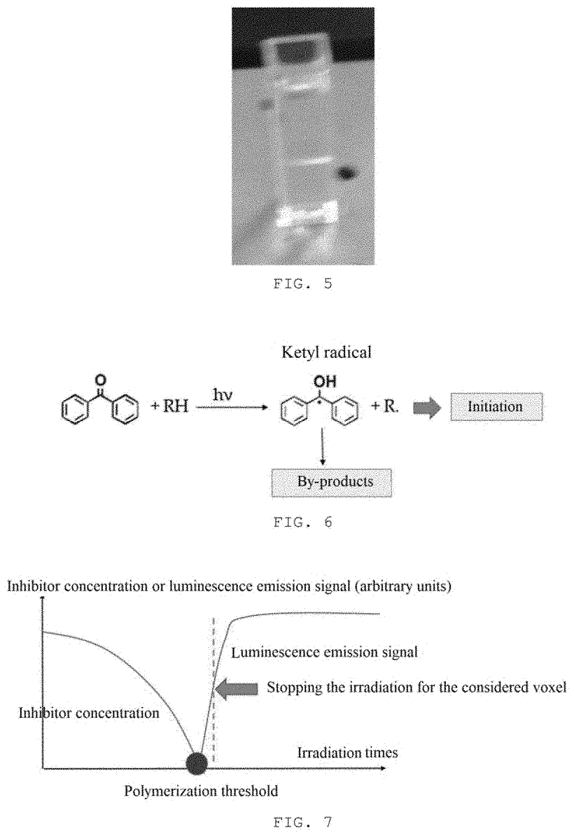

Thanks to the indicator of the amount of polymerization inhibitor present in the reaction medium, it is possible, according to the method of the invention, to monitor the local transformation from liquid to solid, by following the progress of the polymerization in the depth of the fluid forming the reaction medium, without contact, as shown, for example, in FIG. 5.

According to one embodiment, the reaction medium further comprises a photochemical polymerization initiator, capable of initiating the polymerization reaction by absorption of light according to a process with one or more photons. According to a particular embodiment of the invention, the choice of the polymerization initiator is determined, among others, without this being completely restrictive, by the excitation wavelength of the optical indicator, and vice versa. The polymerization initiators according to the invention are known to the person skilled in the art and are described, for example, in the following articles: Yagci Y., Jockusch S., Turro N.J. (2010)—“Photoinitiated Polymerization: Advances, Challenges, and Opportunities” Macromolecules, 43, 6245-6260, and Delaire J., Piard J., Méallet-Renault R., Clavier G. (2016) “Photophysics and photochemistry; fundamentals to applications” EDP Sciences Ed.—Paris. According to one embodiment, the polymerization initiator is selected from ketone compounds such as aromatic ketones, aromatic derivatives, eosin Y and other xanthenic dyes. Advantageously, the polymerization initiator is selected from aromatic ketones, such as benzophenone or 2,2-dimethoxy-1,2-phenyl acetophenone (DMPA), marketed under the name Irgacure 651 (registered trademark), eosin Y for polymerizations in the visible range, or thermal initiators such as benzoyl peroxide for photo-polymerizations in the IR range or else other xanthenic dyes. Initiators particularly adapted for the method according to the invention are benzophenone or the compounds marketed under the trade names (registered trademarks) Darocure 1173 and 116, Quantacure PDO, Irgacure 184, 651 and 907 and Trigonal 14. Benzophenone, of which the decomposition in free radicals after absorption of a photon of suitable energy is shown in FIG. 6, is a preferred polymerization initiator, according to the invention.

Von Raumer M., Suppan P., Jacques P. (1997) “Photoinduced charge transfer processes of triplet benzophenone in acetonitrile” J. Photochem. Photobiol., A105, 21-28—mention in the case of benzophenone (or derivatives of this molecule), the possibility of reactions between triplets leading to reactive species. The production of these electronic states is indeed a one-photon process, but it is the bimolecular reaction between triplets which induces a nonlinear process which is exploited. Varadan V. K., Jiang X., Varadan V. V. (2001) “Microstereo-lithography and other fabrication techniques for 3D MEMS” John Wiley & Sons Chichester—UK—have also used this type of initiation method for laser micro-stereo-lithography.

According to one embodiment, the reaction medium can further comprise a filler. For the purposes of the invention, the term “filler” means a material, or a particulate material in the broad sense, which is added to the reaction medium, but which does not participate in the polymerization reaction, as defined and detailed in application FR16/59211. The filler can be considered as inert with respect to the polymerization.

The polymerization carried out during the method of the invention is localized and initiated by a mono-photon or multi-photon absorption, which are preferably mono-photon or bi-photon. According to one embodiment of the invention, the polymerization of the monomers or of the oligomers is initiated by a mono-photon absorption by the initiator. According to another embodiment, the polymerization of the monomers or of the oligomers is initiated by a multi-photon absorption, that is to say a sequential or simultaneous absorption of several photons of suitable wavelengths. For example, a sequential or simultaneous absorption of two, three or even four photons. According to this embodiment, the polymerization is preferably initiated by the sequential or simultaneous absorption of two photons.

The choice of the mono-photon or multi-photon photo-polymerization wavelength, in particular with one or two photons, is determined by the choice of the polymerization initiator and its ability to generate reactive species, under the effect of irradiation. The latter gradually generate polymerization.

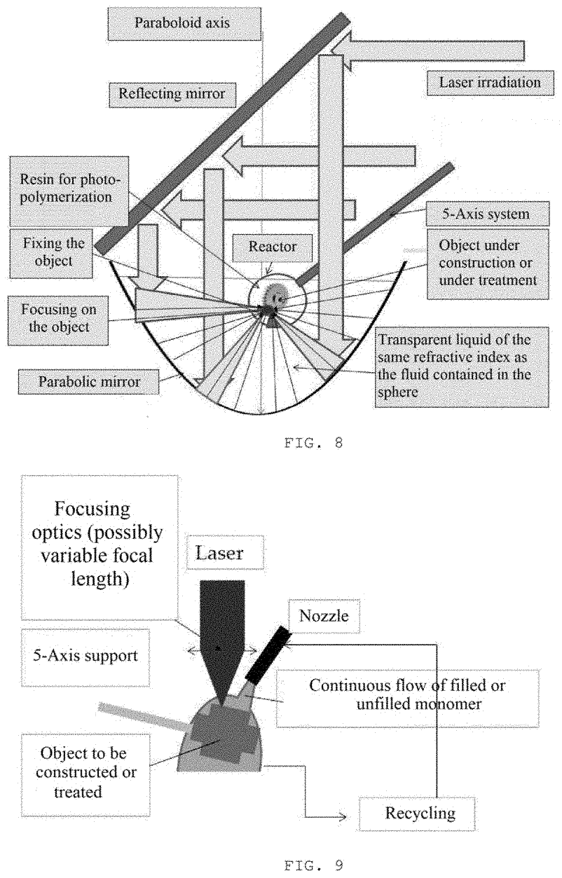

According to the invention, the irradiation system, advantageously comprising a laser, allows the emission of a locally focused light beam. The focusing of the light power, or in other words the confinement of the electromagnetic energy in a narrow region of space, can be obtained by any means known to the person skilled in the art. For example, this focusing can be made possible by components of mirror or lens type implementing reflection or refraction processes, which are direct or secondary, linear or non-linear, by a pulsed laser, typically a picosecond pulsed laser, or by liquid crystal blocks or arrays. According to a particular embodiment of the invention, the focusing of the light power results from the use of a set of fixed parabolic mirrors. An example of such an embodiment is schematically shown in FIG. 8. The parabolic mirror allows a larger solid focusing angle when using laser irradiation to focus light energy at a point of the object to be transformed photochemically. The shape of the voxels will approach, in this case, a spherical shape.

Once the polymerization has started, the amount of polymerization inhibitor present in the voxel is indicated by the indicator of the amount of inhibitor.

According to one embodiment, the amount of inhibitor present is indicated by an optical indicator. This optical indication is given in particular either, by measuring the amplitude of the molecular emission signal, or by measuring the lifetime of the electronic excited state precursor of the molecular fluorescence and/or phosphorescence. These measurements are conventional in photo-physics. In this case, the indication of the amount of inhibitor comprises measuring the light intensity of the optical indicator, using an optical sensor capable of measuring the light intensity of the optical indicator or its evolution over time. According to one embodiment, the optical indicator is luminescent following the absorption of a photon, and the light intensity emitted by the optical indicator is dependent on the amount of polymerization inhibitor present in the zone to be polymerized. In other words, after absorbing a photon emitted by the irradiation system, the optical indicator emits a light intensity by a phenomenon of fluorescence and/or phosphorescence (at wavelengths greater than those of irradiation), and this light intensity emitted by the optical indicator is dependent on the amount of polymerization inhibitor present in the zone to be polymerized. According to a particular embodiment, the polymerization inhibitor is oxygen and the luminescence of the optical indicator is altered, or even extinguished, by the presence of oxygen (decreasing amplitude of the signal in continuous excitation, lifetime of the excited state precursor of the fluorescence and/or phosphorescence in pulsed excitation when the concentration of the inhibitor increases). The lifetime of the excited state responsible for the luminescence of the optical indicator is comprised in a sufficiently long time window to allow to distinguish the excitation from the emission of luminescence. According to a particular embodiment, the lifetime of the excited state responsible for the luminescence of the optical indicator is of the order of 200 ns to 2 ms, preferably of the order of 400 ns to 1 ms.

According to one embodiment, the locally focused light beam emitted by the irradiation system allows both the initiation of the polymerization and the excitation of the optical indicator (molecular probe).

According to another embodiment, the irradiation system allows the emission of the locally focused light beam allowing the initiation of the polymerization and further comprises an excitation system at an absorption wavelength of the optical indicator. This excitation system is particularly adapted for a polymerization initiated by a multi-photon absorption, insofar as the locally focused light beam emitted by the irradiation system is then a multi-photon beam while the optical indicator reacts at a mono-photon absorption. In other words, the locally focused light beam emitted by the irradiation system allows the excitation of the polymerization initiator, by a multi-photon excitation, while the excitation system at an absorption wavelength of the optical indicator allows the mono-photon excitation of the optical indicator.

The method according to the invention allows the control of the amount of light emitted by the irradiation system relative to the amount, or relative to the concentration threshold, of the inhibitor. Thus, according to the method of the invention, the amount of light emitted by the irradiation system in the zone to be polymerized is controlled relative to the amount of polymerization inhibitor present in this same zone, or voxel, according to the indication given by the indicator of the amount of inhibitor. According to one embodiment of the invention, the irradiation system stops the irradiation of the voxel considered when the indicator indicates the absence of polymerization inhibitor in this voxel, in other words when the polymerization inhibitor has been consumed. According to a particular embodiment of the invention, the irradiation system stops the irradiation of the considered voxel when the optical indicator emits light.

According to a particular embodiment of the method of the invention wherein the polymerization is initiated by mono-photon absorption, the reaction medium comprises the polymerizable monomers or oligomers HDDA, oxygen as polymerization inhibitor and 2,3-butane-dione as an indicator of the amount of said inhibitor. Under the locally focused light beam emitted by the irradiation system and in the absence of oxygen, 2,3-butanedione becomes phosphorescent at room temperature, as shown in FIGS. 5 and 7, and its emission at the focal point instantly gives information on the polymerization at this point. This artifice overcomes a control of the oxygen concentration in the polymerization reactor located in space. It is the appearance of the phosphorescence emission which provides information on the polymerization, giving the signal to polymerize the next voxel. FIG. 7 which shows the evolution of the concentration of the inhibitor and of the luminescence emission signal of the optical indicator as a function of the irradiation time, allows to illustrate what happens with the biacetyl which emits a phosphorescence at 515 nm.

When the indicator of the amount of inhibitor indicates that there is no longer any inhibitor in the zone to be polymerized, the irradiation system stops irradiating this voxel. “Means for moving the object and/or the focused light beam” are then implemented in order to polymerize another zone. The means for moving the object and/or the focused light beam thus allow to switch from one voxel to another, during the manufacture of the three-dimensional object or the modification of the surface state of the preformed object. According to one embodiment of the invention, these means for moving the object and/or the focused light beam allow movement along five axes: three linear axes synchronized with two rotary axes.

According to one embodiment, the focused light beam is stationary and the object is animated by movements along the five axes. Examples of this embodiment are shown schematically in FIGS. 8 and 9.

Advantageously, the movement of the object in the reaction medium allows to ensure the mixing, at least partially, of the fluid, thus replenishing the vicinity of the object under construction with oxygen. The object can thus be animated by a movement along the five axes thanks to a movement of the vessel wherein it is located, or thanks to a movement of a support on which the three-dimensional object is constructed or on which the object preformed is placed. According to the example of FIG. 8, the object, which is placed in a sphere, is immersed in a fluid of iso-refractive index, so as not to have to take into account problems of diopters and thus to avoid possible focusing difficulties. According to another embodiment, the reaction medium is constantly replenished with the polymerization inhibitor, to achieve the objective of the presence of the desired inhibitor with a high regulation power, in other words to keep the concentration of polymerization inhibitor in the reactor (accuracy of the order of a few tens of %) as constant as possible. According to the example of FIG. 9 illustrating this embodiment, the reaction medium is constantly replenished with oxygen during the recycling process. Advantageously, according to this embodiment, the recycling process can comprise resin wherein air, or else oxygen is bubbled.

According to another embodiment, the object is stationary and the focused light beam is animated along the five axes. The means for moving the focused light beam then allow, for example, a movement of the irradiation system or a movement of the focused light beam, using for example a set of mirrors and lenses on the optical path or the movement of an optical fiber guiding the beam to the zone to be polymerized, while maintaining the irradiation system fixed.

The method according to the invention thus allows to produce three-dimensional objects, but also to use preformed objects on which material is added, for example, for the repair of industrial metal or organic material parts.

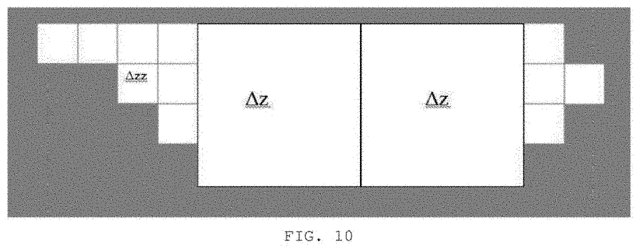

By placing the object thus produced, a surface finish is carried out by the implementation of the method of the invention which does not use the placement of resin layers and which allows a transformation of media that do not scatter light in depth. Under these conditions, the purposes summarized in FIG. 10 are reached. In FIG. 10 and for simplicity of presentation, it is assumed that the voxels are cubes and that the preformed object has, for example, at least a first size resolution Δz. When the surface state is modified, the method of the invention allows to obtain a second, finer resolution, allowing to produce voxels Δzz of smaller size. The relationship between Δz and Δzz is, for example, Δz=10.Δzz. Several voxel size settings can be considered.

By immersing the preformed object in the reaction medium, it is possible to improve its surface state, or even to use other materials to treat the surface thus allowing marking, surface treatment with filled resins, or else coloring. In addition, the number of voxels to be used is substantially proportional to the surface of the object and no longer to its volume. This method allows saving manufacturing time.

During the implementation of the method of the invention, the steps of initiating the polymerization, indicating the amount of inhibitor, controlling the amount of light and switching to a following zone to be polymerized are repeated, iteratively, until the formation of the three-dimensional object or the modification of the surface state of the preformed object.

The method as defined in the invention therefore provides notable improvements to the existing stereo-lithography methods.

Optionally, the method then implements a step of removing the three-dimensional object formed or modified in the vessel. This removal operation can be carried out using any means known to the person skilled in the art, such as removal with the forceps, or else with a sieve, for example.

Then, and also optionally, the method can implement an operation of eliminating, in particular, unpolymerized monomers or oligomers forming for example a film on the three-dimensional object obtained. This elimination operation can be carried out by any means known to the person skilled in the art such as by wiping, using soaking in a bath or else by rinsing with a solvent which dissolves the unpolymerized monomer or oligomer. This removal operation can be carried out at the end of the resin impressions in the mass. In certain cases, a fluidization of the reaction medium, and in particular of at least one unpolymerized monomer or oligomer, can be done by adding liquid monomer or oligomer which allows recycling the non-transformed materials, or using a conventional solvent for the monomer or oligomer. According to a particular embodiment, this removal operation is carried out by rinsing with a solvent, in particular selected from ketone or alcoholic compounds, in particular acetone or else isopropanol.

The invention also relates to a reaction medium for the manufacture of a three-dimensional object or the modification of the surface state of a preformed object as defined above. The reaction medium comprises polymerizable monomers or oligomers advantageously selected from the family of acrylic resins, a polymerization inhibitor, an indicator of the amount of said inhibitor and at least one photochemical polymerization initiator. The information given above and allowing to define and detail the reaction medium of the method of the invention also applies to the reaction medium of the invention as such, insofar as it comprises the same components. Thus, the polymerizable monomers or oligomers, the polymerization inhibitor, the indicator of the amount of said inhibitor and the polymerization initiator are as defined above.

The invention also relates to the use of the indicator of the amount of inhibitor according to the invention, or of the reaction medium according to the invention, to trigger the switching to a following zone to be polymerized in the reaction medium, during a polymerization reaction initiated by mono-photon or multi-photon absorption. The use of the indicator of the amount of inhibitor or of the reaction medium according to the invention allows the control of the amount of light emitted by an irradiation system, in a zone to be polymerized of the reaction medium, relative to the amount of inhibitor indicated by the indicator, thus giving the signal to switch to the following zone to be polymerized.

1. A method for manufacturing a three-dimensional object or for modifying the surface state of a preformed object, by local polymerization of monomers or oligomers, the polymerization being initiated by mono-photon or multi-photon absorption, in a zone to be polymerized, comprising:
introducing, into a vessel with light-transparent walls, a reaction medium comprising polymerizable monomers or oligomers, a polymerization inhibitor, an indicator of the amount of said inhibitor and a polymerization initiator;
initiating polymerization of the monomers and/or oligomers, in a zone to be polymerized, in the reaction medium, by an irradiation system allowing the emission of a locally focused light beam, through the light-transparent walls of the vessel;
indicating an amount of inhibitor present in the zone to be polymerized, by the indicator of the amount of inhibitor;
controlling an amount of light emitted by the irradiation system, in the zone to be polymerized, relative to the amount of inhibitor indicated by the indicator; and
switching to a following zone to be polymerized, in the reaction medium, by moving the object, the focused light beam, or both the object and the focused light beam.

2. The method according to claim 1, wherein the inhibitor is selected from the group consisting of oxygen and hydroquinone.

3. The method according to claim 1, wherein the indicator is an optical indicator of the amount of inhibitor and the indicating of the amount of inhibitor comprises measuring a light intensity emitted by the optical indicator using an optical sensor.

4. The method according to claim 3, wherein the irradiation system further comprises an excitation system at an absorption wavelength of the optical indicator of the amount of inhibitor.

5. The method according to claim 3, wherein the light intensity of the optical indicator of the amount of inhibitor is measured continuously, over time, or both continuously and time.

6. The method according to claim 3, wherein the indicator is a fluorescent or phosphorescent indicator, and a local intensity of fluorescence or phosphorescence of the fluorescent or phosphorescent indicator varies according to the amount of inhibitor.

7. The method according to claim 1, wherein the indicator is selected from the group consisting of 2,3-butanedione, 2,3-propanedione, 2,3-bornanedione, benzene and pyrene.

8. The method according to claim 1, wherein the polymerizable monomers or oligomers are acrylic monomers or oligomers.

9. The method according to claim 1, wherein the object, the focused light beam, or both the object and the focused light are moved so as to allow movement along five axes of the object, the focused light beam, or both the object and the focused light beam, the five axes being formed of three linear axes synchronized with two rotary axes.

10. A reaction medium for the manufacture of a three-dimensional object or the modification of the surface state of a preformed object, comprising:
polymerizable monomers or oligomers,
a polymerization inhibitor,
an indicator of an amount of the polymerization inhibitor, and
a polymerization initiator.

11. A method for manufacturing a three-dimensional object or for modifying the surface state of a preformed object, by local polymerization of monomers or oligomers, the polymerization being initiated by mono-photon or photon absorption, in zone to be polymerized, comprising:
carrying out a polymerization reaction initiated by mono-photon or multi-photon absorption, in a reaction medium according to claim 10, for a first zone to be polymerized in the reaction medium,
switching to a second zone to be polymerized in the reaction medium, during the polymerization reaction initiated by mono-photon or multi-photon absorption, according to an indication of the amount of the polymerization inhibitor provided by the indicator.

12. The method according to claim 2, wherein the indicator is an optical indicator of the amount of inhibitor and the indicating of the amount of inhibitor comprises measuring a light intensity emitted by the optical indicator using an optical sensor.

13. The method according to claim 12, wherein the irradiation system further comprises an excitation system at an absorption wavelength of the optical indicator of the amount of inhibitor.

14. The method according to claim 4, wherein the light intensity of the optical indicator of the amount of inhibitor is measured continuously, over time, or both continuously and over time.

15. The method according to claim 12, wherein the light intensity of the optical indicator of the amount of inhibitor is measured continuously, over time, or both continuously and over time.

16. The method according to claim 13, wherein the light intensity of the optical indicator of the amount of inhibitor is measured continuously, over time, or both continuously and over time.

17. The method according to claim 4, wherein the indicator is a fluorescent or phosphorescent indicator, and a local intensity of fluorescence or phosphorescence of the fluorescent or phosphorescent indicator varies according to the amount of inhibitor.

18. The method according to claim 12, wherein the indicator is a fluorescent or phosphorescent indicator, and a local intensity of fluorescence or phosphorescence of the fluorescent or phosphorescent indicator varies according to the amount of inhibitor.

19. The method according to claim 13, wherein the indicator is a fluorescent or phosphorescent indicator, and a local intensity of fluorescence or phosphorescence of the fluorescent or phosphorescent indicator varies according to the amount of inhibitor.

20. The method according to claim 2, wherein the indicator is selected from the group consisting of 2,3-butanedione, 2,3-propanedione, 2,3-bornanedione, benzene and pyrene.
